(19) United States
(12) Patent Application Publication
(10) Pub. No.: US 2017/0345850 A1
(43) Pub. Date: Nov. 30, 2017

(54) EXFOLIATION LAYER AND FABRICATION METHOD THEREFOR

(71) Applicant: Ceramics & Chemicals Technology Inc., Ulsan (KR)

(72) Inventors: Dong Heon LEE, Seoul (KR); Jeong Seok KIM, Ulsan (KR)

(21) Appl. No.: 15/532,690

(22) PCT Filed: Dec. 2, 2015
(86) PCT No.: PCT/KR2015/013085

§ 371 Date: Jun. 2, 2017

(30) Foreign Application Priority Data
Dec. 3, 2014 (KR) 10-2014-0172121

(51) Int. Cl. H01L 27/12; C09D 139/00; C09D 179/02; H01L 21/683; C09D 7/12; C08K 3/34

(52) U.S. Cl. CPC H01L 27/1266; H01L 21/6835; C09D 7/1216; C09D 139/00; C09D 179/02; H01L 27/1218; C08K 3/346; H01L 2221/68345; H01L 2221/6835; H01L 2221/68381

(57) ABSTRACT

This invention relates to an exfoliation layer composed of a cationic polymer electrolyte or organosilane and negatively charged phyllosilicate sheet-shaped nanoparticles, and to a method of manufacturing the exfoliation layer, including a) negatively charging the surface of a substrate, b) applying a cationic polymer electrolyte or performing a silanization process, and c) negatively charging and applying phyllosilicate. Since the exfoliation layer of the invention has an effect of reducing bonding force due to the sheet-shaped nanoparticles therein, the exfoliation layer enables a flexible display to be temporarily fixed on a supporting substrate upon fabrication of the flexible display and to then be easily separated after the completion of the fabrication thereof.

### CROSS-REFERENCE TO RELATED APPLICATIONS

This Application is a Section 371 National Stage Application of International Application No. PCT/KR2015/013085, filed Dec. 2, 2015, and additionally claims priority to Korea Patent Application 10-2014-0172121 filed on Dec. 3, 2014, the contents of which are each hereby incorporated by reference in its entirety.

### FIELD

The present invention relates to an exfoliation layer for use in the fabrication of a flexible display and to a method of manufacturing the same.

### BACKGROUND

During the fabrication of a flexible display, a material for a substrate preferably includes a polymer resin that is easily flexible or foldable. As in a typical flat-panel display using a glass substrate, a flexible display is fabricated in a manner in which an information control display element such as a thin film transistor (TFT) is formed on a substrate made of a polymer resin and deposition, patterning, washing and the like are conducted on the flexible polymer resin.

A polymer thin-film resin such as polyimide, generally evaluated to be suitable for use in a flexible display substrate, is good in transparency, electrical insulating properties, heat resistance, rigidity, etc. and has low thermal deformation compared to other resins. However, because of damage to the substrate or thermal deformation during a series of procedures for fabricating a flat-panel information control display element, it is difficult to control the position in a precise process such as a photoexposure or shadow-masking process for use in selecting and avoiding the position of the element, making it impossible in practice to manufacture an information control display element.

With the goal of solving such problems, glass, which is typically useful as a material for a display substrate because of high durability and low thermal deformation, is used together with a polymer substrate. Specifically, a flexible polymer such as polyimide is attached to the surface of a glass carrier plate through a film lamination process or a liquid casting process.

The glass carrier plate functions as a planar support for preventing the flexible substrate from being damaged or deformed during the fabrication of an information control display element, and the glass and the flexible thin-film substrate are separated from each other after the completion of processing. This method is advantageous because the process of manufacturing the information control display element may be performed under the same conditions (temperature, chemical exposure, etc.) as in existing glass substrate fabrication processes. The separation of the glass carrier plate and the flexible thin-film substrate, which are attached to each other, is easily implemented in a manner in which a XeCl excimer laser is applied to the rear surface of the glass carrier plate to thus weaken the bonding force between the glass and the polymer substrate. Likewise, exemplarily useful is a method of forming an exfoliation layer between a flexible substrate and a glass carrier plate to be bonded together (Korean Patent Application Publication No. 10-2011-0067045) to induce a phase change of the corresponding layer using a XeCl laser to thereby easily separate the two layers.

Such methods are problematic because the flexible substrate and the glass carrier plate are separated using an expensive laser machine, and productivity is very low due to laser irradiation upon the fabrication of a large-area substrate for mass production of a display, and a laser-irradiated region responds partially sensitively to the status of the substrate and the external environment, undesirably increasing the likelihood of high defect rates.

Furthermore, Korean Patent No. 10-0721702 discloses a method of manufacturing an exfoliation layer by forming an adhesive layer between two layers, wherein an acrylate or silicone adhesive is used, but the effects thereof are unsatisfactory.

### CITATION LIST

Korean Patent No. 10-0721702

### SUMMARY

### Technical Problem

Accordingly, the present invention has been made keeping in mind the above problems occurring upon fabrication of an information control display element of a flexible display, and the present invention is intended to provide a method of easily exfoliating a flexible substrate having an information control display element formed thereon from a glass carrier plate serving as a planar support without deformation or damage and without the need for additional processing such as laser irradiation.

### Technical Solution

Therefore, the present invention provides an exfoliation layer comprising a cationic polymer electrolyte or organosilane, along with negatively charged phyllosilicate sheet-shaped nanoparticles.

The exfoliation layer is manufactured by a) negatively charging the surface of a substrate, b) applying a cationic polymer electrolyte or performing a silanization process, and c) negatively charging and applying phyllosilicate.

### Advantageous Effects

According to the present invention, an exfoliation layer has an effect of reducing the bonding force due to sheet-shaped nanoparticles therein, and thus enables a flexible display to be temporarily fixed on a supporting substrate upon fabrication of the flexible display and to then be easily separated after the completion of the fabrication thereof

### BRIEF DESCRIPTION OF THE DRAWINGS

FIG. 1 is a scanning electron microscope (SEM) image showing the applied phyllosilicate sheet-shaped nanoparticles according to an embodiment of the present invention;

FIG. 2 is an SEM image showing the applied phyllosilicate sheet-shaped nanoparticles according to another embodiment of the present invention; and

FIG. 3 is an SEM image showing the applied phyllosilicate sheet-shaped nanoparticles according to still another embodiment of the present invention.

### DETAILED DESCRIPTION

In the fabrication of a flexible display, a flexible substrate made of a resin that is attached to a supporting substrate made of glass has to stably maintain adhesion under processing conditions for manufacturing an information control display element. Particularly, since the information control display element is manufactured at an exact position on the flexible substrate and is not damaged in the absence of in-plane deformation or partial separation due to blistering between the supporting substrate and the flexible substrate at a high temperature of about 300° C. or more, which is the processing temperature for manufacturing the information control display element, the flexible substrate has to be firmly attached to the supporting substrate. Here, the supporting substrate is made of a hard material having chemical resistance and heat resistance with low thermal deformation, as well as sufficient rigidity to fixedly support the flexible substrate even under severe working conditions during the fabrication of a flexible display, and examples of the material therefor may include glass and quartz. Preferably useful is a material having properties equivalent or superior to those as above.

After the completion of the fabrication of the information control display element, when the flexible substrate is mechanically separated from the supporting substrate, the flexible substrate should be able to be separated within a stress range that does not cause deformation of the flexible substrate, making it possible to manufacture a flexible substrate while protecting the information control display element on the flexible substrate from damage such as deformation and breaking.

Consequently, the flexible substrate should be able to be securely fixed to the supporting substrate, and should be easily mechanically separable even without the use of an additional process, energy or chemicals after the completion of the processing. In the present invention, the interfacial bonding is confirmed to satisfy these two properties under certain critical conditions, and a material for the interfacial layer, in which the bonding force between the flexible substrate and the supporting substrate and the bonding distribution are controlled, and a preparation process thereof are provided.

The polymer material for a flexible substrate may include an organic material that is not sensitive to temperature and is stable across a wide temperature range, and is typically exemplified by polyimide (PI). Depending on the processing conditions for manufacturing the flexible substrate, examples of the polymer material may include, but are not limited to, polyethylene terephthalate (PETE), parylene, polyethylene (PE), polyethersulfone (PES), acryl, naphthalene, polycarbonate (PC), polyester, polyurethane (PU), polystyrene (PS), and polyacetylene, and other known organic materials may also be used.

As for a typical polymer thin-film material, expansion or shrinkage due to heat is an inevitable reaction that occurs in all materials, although there is a difference in the extent thereof In the case where the corresponding thin film is applied on a base substrate such as glass having little thermal deformation, an effective process for minimizing thermal in-plane deformation serves to firmly connect and bind the thin film and the base substrate to each other by means of linkers present on individual surfaces. Here, the linker is a bonding source for connecting two different surfaces from a physicochemical point of view, and may refer to a dipole, radical, ligand, electric charge or surface roughness formed on the surface, and the term “bind” indicates “bonding” of the corresponding bonding source to the bonding source of the counterpart surface. These linkers have different bonding forces depending on the kind thereof, and the case where only one kind of linker is present is hard to find in reality, and the thin film may be bonded and fixed to the base substrate by the use of a combination of two or more linkers.

Although whether or not thermal deformation and exfoliation of the thin film may occur greatly depends on the strength of the linkers, namely the magnitude of the bonding force thereof, it may be more greatly affected by the linker distribution and density. If the linkers are non-uniformly distributed at large intervals, the portions of the thin film within the range between the linkers may undergo in-plane deformation.

However, even in the case of linkers having low strength, when they are linkers in which the bonding sources are uniformly distributed at short intervals within the critical distance, the deformation of the thin film may be appropriately suppressed. In this case, the exfoliation process for vertically pulling and mechanically separating the thin film from the base substrate will be naturally and easily realized because the bonding is performed using linkers having low bonding strength. Preferably, in the case where linkers having low bonding strength are uniformly distributed at a minimum density able to suppress deformation and exfoliation of the thin film on the glass base substrate, mechanical exfoliation of the thin film becomes possible even at lower stress.

The bonding (or attachment) between polymers is mainly dependent on covalent bonding, whereas the bonding of the polymer to a material such as glass, silicon, metal or ceramic is achieved using secondary bonding such as hydrogen bonding, either alone or in a combination of covalent bonding and ionic bonding. In the bonding mechanism for attaching a resin for a flexible substrate such as polyimide to a supporting substrate such as glass, in the case of glass and quartz, hydrogen-bridging bond between a silanol group (Si—O—H) formed on the surface of silicon oxide and a hydrogen group of the polymer is mainly formed, and also covalent bonding may be mainly formed depending on the kind of supporting substrate, such as metal oxide and metal, and the kind of polymer for the thin film.

When the resin, which is applied in the form of a thin film on the glass base substrate, is exposed to external stimuli such as plasma or high temperatures during the processing of the flexible display, it is reported that the hydrogen bonding, corresponding to the secondary bonding, partially changes to primary bonding, such as ionic bonding, due to the features of the molecular structure of the polymer to thereby enhance the bonding force. Upon actual fabrication of the flexible display, the polyimide flexible substrate applied on the glass supporting substrate is drastically increased in bonding force due to continuous exposure to high temperatures and external stimuli such as plasma, and thus, after the completion of the processing of the information control display element, there occur frequently some cases where the element such as a thin film transistor and the like may often be damaged on the flexible substrate due to the tearing of the thin film upon physical exfoliation or deformation above the elastic limit.

Consequently, even when weak bonding sources that may be bonded to the resin thin film are uniformly distributed on the surface of a glass base substrate at an early stage, the bonding strength of the bonding sources is increased through additional processing due to the characteristics of the molecular structure of the polymer. Accordingly, taking into consideration changes due to external stimuli such as plasma activation as well as pressure and temperature, even when bonding between the resin thin-film substrate and the base substrate has the changed strong strength, methods that facilitate mechanical exfoliation are required. Furthermore, it is difficult in practice to control the surface of the base substrate so that bonding sources having artificially low bonding strength are uniformly distributed at low density on the entire surface of the base substrate. This is because the status of the bonding sources is an inherent property of the materials for the base substrate, such as the supporting substrate, and the thin film of the flexible substrate.

In order to solve the above two problems, there are devised methods in which additional objects, which function as domains having surface bonding sources at a density lower than that of the bonding sources formed on the supporting substrate such as glass, are arranged in a plane and are disposed between the base substrate and the thin film. The domain objects having the bonding sources at low density may be appropriately thin sheet-shaped nanoparticles (nanosheets) having a high width (diameter)-thickness ratio. The thin film comprising the corresponding domains is additionally applied on the surface of the base substrate such as glass for a supporting substrate, and the resin thin film to be used as a flexible substrate may be further applied thereon through a conventional film lamination process or liquid casting process.

The sheet-shaped nanoparticles that constitute the intermediate thin film have bonding sources at low density on both sides thereof, and thus enable the flexible substrate bonded thereon and the supporting substrate bonded thereunder to undergo mechanical exfoliation at low stress between the intermediate thin film and the supporting substrate or between the intermediate thin film and the flexible substrate after the completion of the fabrication of the flexible display. In the present invention, such an intermediate thin film is referred to as an exfoliation layer.

The sheet-shaped nanoparticles, corresponding to the domains that constitute the exfoliation layer, may be configured such that the kind of bonding source of the object surface and the distribution thereof may be controlled by selecting materials having properties different from those of the supporting substrate or flexible substrate or by performing additional surface treatment. As described above, the top of the sheet-shaped nanoparticles of the exfoliation layer are bonded to the polymer for a flexible substrate through hydrogen bonding, and the bottom thereof may be bonded to the base substrate such as the glass supporting substrate through a combination of secondary bonding such as van der Waals force and electrostatic force.

After the completion of the fabrication of the flexible display, the bonding of the sheet-shaped nanoparticles and the flexible substrate polymer at the upper position is changed into primary chemical bonding such as ionic bonding due to the characteristics of the molecular structure of the polymer, thus retaining strong bonding force. However, since the density of the surface bonding sources is designed to be lower than that of the supporting substrate, such as glass, the fixed state of the sheet-shaped nanoparticles and the flexible substrate facilitates exfoliation relatively well compared to the directly fixed state of the supporting substrate, such as glass, to the polymer. Moreover, since the sheet-shaped nanoparticles are designed to prevent changes to bonding sources from occurring under variation in external conditions, the secondary bonding thereof to the supporting substrate such as glass at the lower position is maintained, and thus mechanical exfoliation may be easily progressed even at low stress.

In the bonding of the exfoliation layer designed in the present invention to the glass base substrate, the sheet-shaped nanoparticles may be directly applied on the supporting substrate, and an additional polymer may be applied between the sheet-shaped nanoparticles and the glass base substrate in order to achieve bonding of the sheet-shaped nanoparticles, as necessary. In the latter case, the corresponding polymer plays a role only in bonding the exfoliation layer to the glass base substrate, and thus has to be formed as thinly as possible.

The sheet-shaped nanoparticles, which constitute the exfoliation layer, are ideally composed of sheet-shaped single-layer particles as basic unit structures comprising atoms or molecules having inherent properties, but the exfoliation layer may be configured such that sheet-shaped particles are in a multilayer structure or are in a combination layer structure of a single layer and single-layer particles. In the case of the multilayer structure or the combination layer of the sheet-shaped nanoparticles, interlayer bonding force is designed to be sufficiently greater than the bonding force between the surface of the sheet-shaped nanoparticles and the flexible substrate or supporting substrate, and thus, the total thickness of the sheet-shaped nanoparticles, namely the thickness of the exfoliation layer, does not affect the function of the exfoliation layer. The inner thin-film configuration of the exfoliation layer may be designed with one or more kinds of sheet-shaped nanoparticles that may be disposed in a plane. Specifically, the exfoliation layer may be configured such that various kinds of sheet-shaped nanoparticles having different properties are provided in the form of a single layer, multiple layers or a combination layer.

The sheet-shaped nanoparticles of the exfoliation layer are preferably formed at a uniform thickness. However, in the case where the polymer of the flexible substrate is applied in a liquid phase or gas phase, when a difference in thickness between the thin sheet-shaped nanoparticles and the relatively thick particles falls in the thickness range of the polymer thin film, there is no problem in the formation of an information control display element on the polymer thin film. Also in the case where a solid-phase film is attached through a film lamination process, the information control display element may be formed on the polymer thin film within a range that does not cause upward dimensional deformation by absorbing elastic deformation in the thickness direction of the polymer. Accordingly, the thickness of the exfoliation layer comprising the sheet-shaped nanoparticles is not particularly limited, so long as it falls in the specific ratio range depending on the thickness of the polymer thin film applied on the exfoliation layer.

The sheet-shaped nanoparticles, which constitute the exfoliation layer, have to possess superior deformation resistance and microstructure stability to heat, and in particular, thermal deformation or decomposition, which may affect the flexible substrate and the information control display element formed thereon, should not occur in the temperature range of 100 to 500° C. Furthermore, the sheet-shaped nanoparticles in single-layer or multilayer form are preferably sheet-shaped particles having a width-thickness ratio (an aspect ratio, obtained by dividing width by thickness) of 5 or more, a thickness of 0.5 nm to 300 nm, and a width of 10 nm to 100 μm. Moreover, the density of bonding sources should be lower on the surface of the sheet-shaped nanoparticles than on the supporting substrate such as glass, and the sheet-shaped nanoparticles are surface-charged in a specific solution, especially an aqueous solution, and thus the dispersion state thereof has to be maintained efficiently.

The material for the sheet-shaped nanoparticles having the above characteristics may be selected from among natural silicate minerals. However, among crystalline silicate minerals, sorosilicate, cyclosilicate, inosilicate, tectosilicate and orthosilicate have unit lattices having a square or acicular shape, and are thus unable to delaminate into sheet-shaped particles, making them unsuitable for the manufacture of sheet-shaped nanoparticles necessary for the present invention. On the other hand, when phyllosilicate having cleavage characteristics with a lamellar crystal structure, among crystalline silicates, is used, it is possible to manufacture sheet-shaped nanoparticles responsible for domains described in the present invention. In particular, the delaminated particles of phyllosilicate manifest excellent high-temperature stability, and the delaminated particles are naturally negatively charged and are thus easily dispersed in a solution, and may be attached to the supporting substrate, such as glass, through secondary bonding such as van der Waals force and electrostatic force. Furthermore, since the density of the silanol group (Si—O—H) acting as the bonding source on the surface of the particles is lower than that of glass, the bonding force thereof to the polymer is relatively low. In practice, the density of silanol on the surface of lamellar particles of muscovite (K[Si₃Al]O₁₀Al₂(OH)₂), which is a kind of phyllosilicate, is reported to be considerably lower than that of glass.

In the typical process of manufacturing phyllosilicate sheet-shaped nanoparticles, an intercalation process for increasing the layer spacing is performed in a manner in which positive atoms or ions (these chemical species are called a guest, and parent crystals for the layer are called a host) are artificially inserted into the phyllosilicate in the solution through physical, chemical or electrochemical processing, after which the intercalated phyllosilicate suspension is subjected to a physical process such as sonication or a chemical reaction with the guest using molecules or atoms in the solution, thereby exfoliating a layered structure into individual layers, resulting in sheet-shaped nanoparticles. Depending on the kind of phyllosilicate, it may be exfoliated into sheet-shaped nanoparticles during the process of exchanging interlayer guest cations with water molecules having dipole characteristics.

Depending on the status of alternation of an Si—O tetrahedral layer (T) and an M—O (where M is Al, Fe, or Mg) octahedral layer (O), the phyllosilicate may be of a 1:1 type (T-O), a 2:1 type (T-O-T), and a combination type, and may be selected from a clay mineral group, a mica group, a chlorite group, a serpentine group, and a kaolinite-serpentine group as the combination type. In the serpentine group of phyllosilicate, antigorite and chrysotile, which is a material found in asbestos, have a crystal structure in which the lamellar structure is grown long in a tubular or fibrous shape, making it difficult to manufacture sheet-shaped nanoparticles. Other kinds of phyllosilicate vary therebetween in difficulty of intercalation and exfoliation, but may be manufactured into sheet-shaped nanoparticles necessary for the present invention.

In particular, the clay mineral group is a relatively easy material for manufacturing sheet-shaped nanoparticles, compared to other kinds of phyllosilicate, and is subdivided into a kaolinite group or a kaolinite-serpentine group, an illite group, a smectite group, and a vermiculite group. Also, pyrophyllite, montmorillonite, beidellite, nontronite, talc, saponite, hectorite, and sauconite, belonging to the smectite group having swelling properties, which cause lattice expansion during hydration, in which water molecules penetrate between layers, and kaolinite, dickite, nacrite and halloysite, belonging to the kaolinite group, are materials suitable for use in manufacturing the sheet-shaped nanoparticles that constitute the exfoliation layer according to the present invention. As artificially synthesized phyllosilicate, laponite, in which the hectorite structure is made using specific exchange ions such as Mg and Li, has the same characteristics as the smectite group, and is thus suitable for manufacturing the sheet-shaped nanoparticles.

Montmorillonite and vermiculite of the smectite group, which are the main ingredients of bentonite and have a T-O-T structure, are intercalated with interlayer ion-exchangeable cations such as Li⁺, Na⁺, Mg²⁺, and Ca²⁺, whereby water molecules or large polymer ions (anion electrolyte) may penetrate between the layers using an aqueous solution or electrolyte solution so as to exfoliate the layers, thereby facilitating the formation of sheet-shaped nanoparticles. The single-layer sheet-shaped nanoparticles of kaolinite, having a T-O structure (1:1 type), have a thickness of about 0.5 nm, and the single-layer sheet-shaped nanoparticles of pyrophyllite, illite and montmorillonite, having a T-O-T structure (2:1 type), have an average thickness of about 0.96 nm.

Phyllosilicate, excluding the clay mineral group, may include a mica group such as sericite, muscovite, biotite, and phlogopite, thus being suitable for the manufacture of sheet-shaped nanoparticles. Mica has a T-O-T structure, in which potassium (K+) having a small atomic radius is present between layers and thus the interlayer spacing is small compared to the clay mineral group, and the bonding to the host crystal is relatively strong, and thus mica is difficult to exfoliate because there are no swelling properties due to water molecules, compared to the clay mineral. However, sheet-shaped nanoparticles may be manufactured through known techniques, including solvothermal intercalation in an autoclave using an alkali metal aqueous solution such as potassium hydroxide (KOH) and exfoliation using microwaves or sonication. The sheet-shaped particles of mica have a thickness similar to that of kaolinite, and a width (diameter) greater than that of typical clay minerals, and are thus favorable for use as sheet-shaped nanoparticles that constitute the exfoliation layer corresponding to the domains applied on the supporting substrate.

In the present invention, the phyllosilicate suitable for manufacturing the sheet-shaped nanoparticles may include any one or a combination of two or more selected from among the above materials.

Typically, the thickness of a flexible polymer thin-film substrate is appropriately set to the range of 5 μm to 200 μm in order to ensure flexibility, and an exfoliation layer is preferably formed to a thickness that falls in the range of 0.01% to 10.0% of the thickness of the corresponding flexible substrate. The minimum thickness of the exfoliation layer is formed of only a single layer of phyllosilicate, and the minimum thickness of the single layer of the phyllosilicate sheet-shaped nanoparticles is 0.5 nm, like the thickness of the single layer of the kaolinite, and thus the exfoliation layer cannot be formed to a thickness less than the above minimum thickness. In the case where the exfoliation layer is composed of single-layer or multilayer sheet-shaped nanoparticles, if the thickness thereof exceeds 10% of the thickness of the flexible polymer substrate, a difference in height of the distributed nanoparticles is significantly great, and may cause the upper flexible substrate to protrude. Hence, the thickness of the exfoliation layer has to fall in the range of 10% or less thereof. More preferably, the thickness of the exfoliation layer falls in the range of 0.05% to 1.0% of the thickness of the designed flexible substrate, within the scope of the present invention.

In order to form the phyllosilicate sheet-shaped nanoparticles as the exfoliation layer on the supporting substrate, such particles are dispersed in a liquid, and are then applied through a known process such as a layer-by-layer self-assembly (LbL) process, as will be described later. In the course of applying the sheet-shaped nanoparticles using an LbL process, the electric charge state of the surface of the particles that constitutes the suspension and the extent of dispersion thereof are regarded as very important. Thus, the surface charge characteristics of the phyllosilicate sheet-shaped nanomaterial are to be understood.

The surface of the silicate sheet-shaped nanoparticles, which are dispersed in the aqueous solution, is negatively charged due to the structural features of Si, O, Al, Mg, or Fe atoms. In an example of the smectite group, montmorillonite or kaolinite phyllosilicate is configured such that the Si⁴⁺ atom of the tetrahedral layer is substituted with an Al³⁺ atom, and also such that the Al³⁺ atom of the octahedral layer is substituted with an Mg²⁺ and the Mg²⁺ atom is substituted with an atom such as Li⁺, whereby the surface of each layer is negatively charged. The negative charge is mainly originated from an OFF radical or an O⁻ radical, and the extent thereof varies depending on the internal impurities of phyllosilicate and the peripheral conditions. The surface charge state of the sheet-shaped nanoparticles of montmorillonite, which is the same kind of phyllosilicate obtained from natural minerals, may vary depending on the origin thereof, but such variation is not great. When the sheet-shaped particles of the smectite group, kaolinite group, vermiculite group, and mica group, which are classified based on the molecular structure of phyllosilicate, are dispersed in solution, the surface charge of all nanoparticles has a negative polarity, but the charge density thereof varies depending on the phyllosilicate group.

In order to bond the charged particles having a negative surface charge to a specific base substrate using the LbL process, the substrate such as glass serving as the base substrate is electrically charged so as to have the opposite charge and is then attached to the surface of the particles through electrostatic force in the solution. The negatively charged phyllosilicate sheet-shaped nanoparticles are attached to the positively charged glass surface and bonded through secondary chemical bonding such as van der Waals force. In this case, the electrically charged sheet-shaped nanoparticles have to be applied on the entire surface of the substrate such as glass. If the region where the sheet-shaped nanoparticles are not attached is present, it may be directly adhered to the flexible polymer formed on the exfoliation layer, and thus the flexible polymer substrate and the supporting substrate are bonded, and it is difficult to efficiently perform the exfoliation process due to strong bonding force of the above region after exposure to external stimulation during the fabrication of the information control display element. In order to prevent this problem, the area where the sheet-shaped nanoparticles of the exfoliation layer are attached to the supporting substrate such as glass, namely the application ratio of the coated area relative to the area to be coated with the sheet-shaped nanoparticles, has to be maximized. In the case where the application ratio is low, even when the exfoliation layer including the sheet-shaped nanoparticles is able to decrease exfoliation stress between the flexible substrate and the supporting substrate, direct bonding of the flexible substrate and the supporting substrate such as glass occurs on the non-coated region, and the likelihood of damage or deformation of the flexible polymer substrate may become very high upon exfoliation thereof due to the strong bonding strength of the corresponding portion.

Therefore, a method of minimizing the contact between the flexible polymer substrate and the supporting substrate such as glass by increasing the application ratio of the sheet-shaped nanoparticles should be taken into account. Assuming that the electric charge state of the supporting substrate such as glass, serving as the counterpart substrate to be coated, and the density of the nanoparticles in the suspension are constant, the application ratio is determined by the charge state, such as the charge density, distribution and polarity, of the sheet-shaped nanoparticles suspended in the solution.

Since the negative charge density of the surface of the phyllosilicate sheet-shaped nanoparticles has a permanent negative surface charge due to the crystal structure of silicate, the dispersion state of colloids in the aqueous solution is maintained through mutual repulsion by particles having a negative surface charge. The charge dstribution of the phyllosilicate sheet-shaped nanoparticles may vary depending on the pH (hydrogen ion concentration, or acidity) of the aqueous solution and the kind and concentration of electrolyte. In the molecular structure of the particles, the charge state of the large surface, corresponding to the tetrahedral and octahedral silica basal planes, is determined by the substitution ions such as Al⁺³, Mg⁺², Li⁺, etc., and the polarity or charge density may vary depending on the kind of phyllosilicate, but is little affected by external conditions such as pH. Meanwhile, the edges of the single-layer or multilayer sheet-shaped nanoparticles have an unstable structure in which the molecular structure is partially broken and have amphoteric properties in which the bonded constituent atoms may react with ions in the solution depending on the external environment, and may be electrically changed into negative, neutral and positive polarities depending on the pH and the kind of electrolyte. Accordingly, using the variability of the external charge state of the phyllosilicate sheet-shaped nanoparticles, the application ratio of the sheet-shaped nanoparticles on the supporting substrate may be maximized.

The effect of pH on the external charge state of phyllosilicate sheet-shaped nanoparticles is as follows. When the suspension is made alkaline at a pH of 7.5 or more, the reactions of Si—OH+OH [symbol] Si—O⁻ and Al—OH+OH⁻ [symbol] Al—O⁻ occur in some of the tetrahedral and octahedral molecular structures of the edges of the particles, and most of the edges of the sheet-shaped nanoparticles are negatively charged. Thus, the sheet-shaped nanoparticles have a permanent negative surface charge and the edges thereof are also negatively charged.

Also, when the pH of the suspension comprising phyllosilicate sheet-shaped nanoparticles is decreased and titrated to an acidic pH of 5.5 or less, the reaction of Al—OH+H⁺ [symbol] Al—OH₂⁺ progresses on the edges of the particles, resulting in a positive charge. The surface of the sheet-shaped particles present in the solution is electrically charged in a permanent negative surface charge due to the molecular structural properties, whereas the edges thereof are positively charged. On the other hand, when the suspension has a pH of 5.5 to 7.5, the upper and lower surfaces of the particles are negatively charged, and the edges of the single-layer or multilayer particles are maintained uncharged, that is, electrically neutral.

Taking into consideration the effect of variability of the charge state of the edges of the particles on the application of the exfoliation layer on the supporting substrate, the particles in the solution may be moved and attached to the supporting substrate such as glass, which is electrically charged to an opposite polarity, by means of the electrostatic attraction due to the permanent negative surface charge of the sheet-shaped nanoparticles, regardless of the pH of the suspension. In the case of a suspension at an alkaline pH, the edges of the phyllosilicate sheet-shaped nanoparticles in the alkaline solution are negatively charged and repulsion occurs between the particles during the approach to the supporting substrate and immediately upon attachment thereto, whereby the particles may be spaced apart from each other at a predetermined distance. Furthermore, the application ratio of the sheet-shaped nanoparticles may be limited due to the presence of the region where the sheet-shaped nanoparticles are not applied. Meanwhile, in the case of an acidic suspension, the edges of the particles suspended in the acidic suspension are positively charged but have the same polarity, and thus mutual repulsion between the particles may occur, making it difficult to apply the particles on the supporting substrate, as in the alkaline suspension. During attachment to the supporting substrate, repulsion may be caused due to the same polarity of the edges in both of the above two cases, making it impossible to decrease the distance between the particles, and limitations are thus imposed on the application ratio of the sheet-shaped nanoparticles that constitute the exfoliation layer.

Hence, the sheet-shaped nanoparticles have to be efficiently dispersed in the solution, and repulsion between the particles should not occur upon attachment to a glass base substrate having the opposite polarity. To this end, pH conditions suitable for an isoelectric point (IEP), at which the edges of the particles become uncharged, that is, electrically neutral, have to be provided, and attachment of the particles close to each other has to be induced in the absence of repulsion therebetween, thereby increasing the application ratio.

In the present invention, the solution added to adjust the pH of the suspension preferably includes inorganic acid or alkali solutions of hydrochloric acid (HCl), nitric acid (HNO₃), sulfuric acid (H₂SO₄), phosphoric acid (H₃PO₄), sodium hydroxide (NaOH), and potassium hydroxide (KOH), acid salts such as Na₂HPO₄, NaH₂PO₄, NaHSO₄, and NaHCO₃, and alkali salts such as Ca(OH)Cl, and Mg(OH)Cl.

Charge heterogeneity of portions of the edges of the phyllosilicate sheet-shaped nanoparticles in the suspension depending on the pH occurs on the microscopic scale, and the above phenomenon of particle dispersion depending on the pH of the suspension is known. However, even in the pH range where the edges of the charged particles have a positive charge, the particles present in the suspension do not behave on a macroscopic scale in a manner depending on the expected charge state. Actually, the particles in the suspension may be subjected to face-to-edge attraction at a pH of 4.0 or less, thereby forming a macroscopic interparticle network and generating coagulation of the particles dispersed in the solution, whereby the suspension is gradually increased in viscosity and thus becomes a gel, and the isoelectric point of the edges of the particles may be expected to fall in the pH range of 4.0 to 5.5.

Under such acidic pH conditions, the molecular structure of the phyllosilicate sheet-shaped particles may be damaged, or the surface charge thereof may be decreased upon long-term maintenance under such conditions, and thus not only the uniform dispersion state maintained by the electrostatic repulsion but also the subsequent process for applying the particles on the supporting substrate such as glass may deteriorate. Furthermore, the strong acidity of the suspension may cause wastewater treatment problems, and the method of improving the extent of dispersion and the application ratio by adjusting the isoelectric point of the edges of the sheet-shaped nanoparticles using only the pH is regarded as undesirable.

The reason why the dispersed phyllosilicate particles behave as negatively charged particles on the macroscopic scale is as follows. Even when the pH of the suspension causes the edges of the particles to be positively charged, the range of the electrical double layer (EDL), in which a permanent negative surface charge is formed, is large enough to cover all of the sheet-shaped nanoparticles having a high aspect ratio, and thus the positively charged EDL of the edges that are lateral sides of the particles is screened with the negatively charged EDL of the surface thereof, and consequently, the edges of the sheet-shaped nanoparticles are positively charged, but all particles behave as negatively charged particles. The face-to-edge repulsion of the sheet-shaped nanoparticles is relatively weak in an acidic suspension, having a low pH, compared to an alkaline suspension, having a high pH. Thus, upon measurement of the viscosity of the suspension, the viscosity may be increased somewhat, but the dispersion state of the particles is still good due to the total negative charge.

Like the pH of the suspension, the major factors that may affect the electric charge state of the sheet-shaped nanoparticles are the kind of electrolyte and the amount thereof in the solution. When the ionic strength of the suspension is increased by adding the electrolyte to the suspension of the phyllosilicate particles, the electric potential around the charged particles decreases, thus reducing the range of surface EDL of the particles. When the reduction in surface EDL reaches a critical value by increasing the concentration of the electrolyte, the screened EDL of the edges of the particles is exposed to the outside. Consequently, the edges of the nanoparticles positively charged in the suspension are changed so as to function as a positive charge by means of the added electrolyte.

As the electrolyte that may be added to the suspension of the phyllosilicate sheet-shaped nanoparticles to form the exfoliation layer of the present invention, an electrolyte, which does not cause a chemical reaction with the dispersed particles and includes a hydrogen ion (H⁺) or a hydroxyl ion (OH⁻) and thus has no direct influence on the pH of the suspension titrated to a desired value, is required.

Preferably useful is an electrolyte having an alkali cation, such as lithium or sodium, including sodium chloride (NaCl), lithium chloride (LiCl), potassium chloride (KCl), potassium nitrate (KNO₃), sodium nitrate (NaNO₃), sodium sulfate (Na₂SO₄), sodium sulfite (Na₂SO₃), sodium thiosulfate (Na₂S₂O₃), and pyrophosphate such as sodium pyrophosphate (Na₄P₂O₇). More preferably useful in the present invention is a 1:1 electrolyte (supporting or indifferent electrolyte) acting as a salt having high decomposition voltage with monovalent ions, such as potassium chloride (KCl), sodium chloride (NaCl), or lithium chloride (LiCl). Even when a multivalent ion electrolyte is added in a very small amount to the suspension, the ionic strength is drastically increased, thus causing coagulation of the particles, and the range of the amount of electrolyte that is added to obtain desired particle properties of the suspension is narrow, and reaction between ions may take place, making it difficult to maintain the isoelectric point pH of the edges of the sheet-shaped nanoparticles.

The concentration of the electrolyte, in which the pH where the charge of the edges of the sheet-shaped nanoparticles in the suspension is maintained in an electrically neutral state, is set to the range of 5.5 to 7.5, appropriately falls in the range of 0.01 mM/L to 200 mM/L (millimoles (mM) per volume (L) of the suspension). If the concentration of the electrolyte is less than 0.01 mM/L, the negatively charged EDL of the surface of the sheet-shaped particles plays a leading role, and thus the charge at the edges of the particles does not appear. On the other hand, if the concentration of the electrolyte exceeds 200 mM/L, the concentration of the electrolyte ions around the particles in the suspension is increased, and electrolyte ions more quickly approach the supporting substrate than the particles by means of electrostatic attraction during the application of the sheet-shaped nanoparticles on the supporting substrate, and thus the density of the sheet-shaped nanoparticles in the exfoliation layer, that is, the application ratio thereof, may decrease, and limitations are imposed on the concentration of the electrolyte. The concentration of the electrolyte is preferably set to the range of 0.05 mM/L to 100 mM/L, and more preferably 0.1 mM/L to 50 mM/L.

In summary, when the suspension has a neutral pH or the pH thereof falls in a specific range close to the neutral pH by adding the appropriate amount of electrolyte to the suspension of the phyllosilicate sheet-shaped nanoparticles, the surface of the single-layer or multilayer sheet-shaped nanoparticles is negatively charged and the edges thereof are electrically neutral. Since the dispersed particles in such a suspension have no edge-to-edge repulsion while being maintained in a good dispersion state through electrostatic repulsion by the surface charge of the particles, no limitations are imposed on application on the supporting substrate such as glass, and thus the application ratio is increased compared to when edge-to-edge repulsion occurs due to the negative or positive charge.

The concentration of the phyllosilicate sheet-shaped nanoparticles in the suspension in which the electrolyte and the pH are controlled in the appropriate range as above is set to the range of 0.01 wt % to 5.0 wt %. If the concentration of the particles is less than 0.01 wt %, the region where the nanoparticles of the exfoliation layer are not attached to the charged glass supporting substrate is enlarged, and the application ratio does not exceed 60%. In this case, the supporting substrate and the flexible polymer substrate that is applied on one side of the exfoliation layer are directly bonded to each other, making it impossible to separate the flexible substrate at a desired low stress. On the other hand, if the concentration of the sheet-shaped nanoparticles exceeds 5.0 wt %, the viscosity of the suspension is increased and the pH may increase, making it impossible to control the isoelectric point of the edges of the particles. During the coating of the supporting substrate, the sheet-shaped nanoparticles may be unnecessarily wasted. Hence, the concentration of the sheet-shaped nanoparticles in the suspension preferably falls in the range of 0.05 wt % to 2.0 wt %, and more preferably 0.1 wt % to 1.0 wt %.

In order to further increase the application ratio of the phyllosilicate sheet-shaped nanoparticles on the supporting substrate such as glass, the kind and concentration of electrolyte and the pH of the isoelectric point of the edges of the sheet-shaped nanoparticles are adjusted to control the charge state of the particles of the suspension.

Also, while the particles are provided at an appropriate concentration, the suspension of the sheet-shaped nanoparticles having one or more size ranges is preferably applied, rather than the exfoliation layer comprising particles having a single size range. Specifically, the particle size in which the sheet-shaped nanoparticles are in a single-layer or multilayer form is set to the range of 10 nm to 100 μm. Given the above size range, the particles of the suspension are preferably configured such that particles having a size of 10 nm to 0.5 μm constitute 5% to 30% of all particles. More preferably, the application ratio may be improved when the proportion of sheet-shaped nanoparticles having a corresponding small size is 10% to 20%. This functions to apply relatively large particles and also to apply small particles between the large particles. Here, the particles having two size ranges may be composed of different kinds of phyllosilicate. For example, the large-sized sheet-shaped nanoparticles may include muscovite of the mica group, and the small-sized particles may include montmorillonite of the smectite group.

In the present invention, a typical process of applying an exfoliation layer on a supporting substrate such as glass is exemplified by a layer-by-layer self-assembly (LbL) process. In the known LbL process, the base substrate, such as a supporting substrate, which is artificially positively or negatively charged, may be immersed in a solution containing charged particles (or polymer electrolyte (polyelectrolyte)) having a polarity opposite the polarity of the base substrate, or the suspension may be subjected to spraying or spin coating on the corresponding base substrate, whereby the charged particles in the solution are attached to the surface of the base substrate due to electrostatic force. These particles are able to form structurally stable bonding on the base substrate by means of hydrogen bonding, van der Waals bonding, or covalent bonding. In this procedure, the charged particles cause charge inversion in which a charge opposite the surface charge of the base substrate is blocked and converted to the polarity of the particles, and the particles are not further applied. In the course of immersion or spraying, the particles applied on the base substrate are subjected to a washing process in which the particles attached in one or more layers are washed with water so that only particles directly and firmly attached to the surface of the base substrate are allowed to remain. After the completion of this process, the base substrate has the polarity of the particles opposite the initial surface polarity, and the corresponding base substrate is immersed again in the solution in which the particles having the polarity opposite that of the primary suspension are dispersed, or such a suspension is sprayed, whereby the particles of the secondary suspension are applied according to the same principle, and excess applied particles are washed with water. As this procedure is repeated, electric polarities alternate and the thin films are stacked stepwise, followed by final washing and drying, resulting in a multilayered thin film.

The surface charging of the supporting substrate is essential for the LbL process for manufacturing the exfoliation layer of the present invention. The surface of the supporting substrate such as glass may be charged through the following known processes. Specifically, the supporting substrate is subjected to surface activation through atmospheric-pressure plasma treatment in an oxygen (O₂) or argon (Ar) atmosphere. The surface of the supporting substrate is negatively charged by forming an oxygen radical between silicon oxide and a hydroxyl group of silanol. Particularly, upon atmospheric-pressure plasma treatment in an argon atmosphere, the metal ions such as Si, Na, B, Al, Mg, and Ca, distributed on the surface of glass, are activated, and thus the glass surface is charged with a positive charge in ionic form, but the intensity of the negative charge of the oxygen atom is relatively high and the entire glass surface is negatively charged.

Upon UV-ozone (Ultraviolet-O₃) surface treatment, the charge density is low compared to the atmospheric-pressure plasma treatment, but the surface of the supporting substrate is negatively charged due to ozone decomposition and partial ionization of the surface element of the supporting substrate.

Alternatively, the supporting substrate such as glass may be immersed in a Piranha solution in which sulfuric acid (H₂SO₄) and hydrogen peroxide (H₂O₂, 30% solution) are mixed at a ratio of 3:1 to 7:1. The Piranha solution is a strong oxidizing agent that accelerates the formation of a hydroxyl group on the glass surface so that the surface of the base substrate is negatively charged. In the case where the Piranha solution is used, it is noted that a base substrate such as glass may be damaged, and thus surface irregularities may be formed.

Taking into consideration the components of glass and the molecular structure thereof, a portion of the surface structure of the base substrate is physically or chemically damaged within a controlled range using atmospheric-pressure plasma, UV, or Piranha etching (which is called “activation”), making it difficult to positively charge the surface of the supporting substrate. In particular, during the processing of the flexible display according to the present invention in air, the surface of the supporting substrate treated as above cannot be maintained in a positively charged state.

If the supporting substrate is composed of silicon (Si) crystals, the surface silicon atom is covalently bonded with a hydrogen atom upon removal of the surface oxide (SiO₂) with a hydrogen fluoride (HF) aqueous solution to give a hydrogen-terminated silicon surface, resulting in a positively charged state in which hydrogen ions (H+) are distributed. This surface is able to stably maintain the positively charged state for several minutes, even in air. However, glass, which is composed mainly of SiO₂, is not covalently bonded with H, making it impossible to realize a positive charge.

The surface of the supporting substrate such as glass may be positively charged using a polymer molecule that is positively charged through ionization in a polymer electrolyte (polyelectrolyte) aqueous solution. Examples of the cationic polymer electrolyte (polycation) may include PEI (poly(ethylene imine)), PDDA (poly(diallyldimethylammonium chloride)), PAA (poly(amic acid)), PSS (poly(styrene sulfonate)), PAA (poly(allyl amine)), CS (Chitosan), PNIPAM (poly(N-isopropyl acrylamide)), PVS (poly(vinyl sulfate)), PAH (poly(allylamine) hydrocloride) and PMA (poly(methacrylic acid)). The cationic polymer is not limited to the above-listed examples, and any polymer may be used, so long as the independent molecule is sufficiently positively charged.

When the ionic polymer electrolyte is applied to the LbL process for manufacturing the exfoliation layer of the present invention, any one or a combination of two or more selected from the cationic polymer electrolyte group or another cationic polymer is prepared into an aqueous solution, and the supporting substrate such as glass, the surface of which is negatively charged through atmospheric-pressure plasma as above, is immersed in the corresponding aqueous solution, whereby the surface thereof is positively charged. Here, the polymer electrolyte is used not to form a specific coating layer of the electrolyte component but to realize charge inversion for forming a polarity opposite that of the sheet-shaped nanoparticles in order to apply negatively charged phyllosilicate sheet-shaped nanoparticles that constitute the exfoliation layer of the present invention. Hence, the polymer electrolyte is preferably applied as thinly as possible.

The thickness of the cationic polymer electrolyte falls in the range of 0.5 nm to 10 nm, and more preferably 1.0 nm to 5 nm, thereby inducing charge inversion of the supporting substrate such as glass. If the thickness thereof is less than 0.5 nm, the corresponding polymer is not partially applied, or the negative charge potential of the base substrate may have an influence thereon, which is undesirable. On the other hand, if the cationic polymer electrolyte is applied to a thickness greater than 10 nm, the relatively soft coating layer may cause thermal deformation of the flexible substrate, and gas that may adversely affect the information control display element of the flexible substrate may be generated by phase transition at high temperatures. Hence, the thickness thereof is controlled to 10 nm or less.

As another alternative to positively charging the supporting substrate such as glass, silanization, useful in biological fields, for example, protein, DNA, etc., may be performed. The materials for forming a hydroxyl group (OH) on the base substrate surface, such as glass, silicon, or alumina (aluminum oxide), are able to induce functionality of organosilane on the surface thereof so as to provide a positive charge. The organosilane is represented by a general formula of (X)₃SiY, wherein X is an alkoxy ligand such as —OCH₃ or —OCH₂CH₃ or a halogen ligand such as —Cl, and Y is an organofunctional group such as aminopropyl, methacryloxy, glycidoxy, or vinyl. Specifically, an amine material such as APS (3-aminopropyltriethoxysilane) and AEAPS (N-2-aminoethyl-3-aminopropyltrimethoxysilane) may be used. During the surface silanization of the supporting substrate, such as glass, the formation of silanol of the hydroxyl group is the same as in the LbL process, but various methods of covalently bonding silane with silanol are known, and may be carried out through known techniques disclosed in many references, and the organosilane coating layer is preferably controlled to the same thickness as in the cationic polymer electrolyte.

The above description is summarized as follows.

Upon the fabrication of a flexible polymer substrate for a flexible display, the flexible substrate is not directly attached to a supporting substrate, such as glass, but an exfoliation layer is formed to facilitate the separation of the flexible substrate from the supporting substrate.

Examples of the polymer for use in the flexible substrate may include polyimide (PI), polyethylene terephthalate (PETE), parylene, polyethylene (PE), polyethersulfone (PES), acryl, naphthalene, polycarbonate (PC), polyester, polyurethane (PU), polystyrene (PS), and polyacetylene, but are not limited thereto, and other known organic materials may also be used.

In order to control the kind and strength of bonding of the exfoliation layer to the flexible substrate and the supporting substrate, the exfoliation layer is preferably configured such that several independent domains are formed, rather than a single integrated domain.

The exfoliation layer present between the flexible substrate and the supporting substrate is composed of independent objects in which low-strength bonding sources are uniformly distributed at low density, and such objects, functioning as domains, are preferably sheet-shaped nanoparticles having a high aspect ratio.

The thickness of the exfoliation layer preferably falls in the specific ratio range depending on the thickness of the flexible polymer thin film applied on the exfoliation layer, and is not limited to the specific range. Typically, the thickness of the flexible substrate on the exfoliation layer falls in the range of 5 μm to 200 μm, and the exfoliation layer including sheet-shaped nanoparticles is preferably formed at a thickness corresponding to 0.01% to 10.0%, and more preferably 0.05% to 1.0% of the thickness of the flexible substrate.

The exfoliation layer is not partially separated due to blistering even upon exposure to severe conditions for manufacturing the information control display element on the flexible substrate, and deformation of the flexible substrate on the exfoliation layer is not caused, and the flexible substrate may be mechanically separated under low stress, which does not damage the flexible substrate or the information control display element on the flexible substrate after the completion of processing.

The sheet-shaped nanoparticles of the exfoliation layer are made of phyllosilicate, the phyllosilicate being selected from a clay mineral group, a mica group, a chlorite group, and a kaolinite-serpentine group.

In the clay mineral group, examples of the material able to be used in the manufacture of sheet-shaped nanoparticles may include a kaolinite group or a kaolinite-serpentine group, an illite group, a smectite group, and a vermiculite group.

In the kaolinite group, examples of the material able to be used in the manufacture of sheet-shaped nanoparticles may include kaolinite, dickite, nacrite, and halloysite.

In the smectite group, examples of the material able to be used in the manufacture of sheet-shaped nanoparticles may include pyrophyllite, montmorillonite, beidellite, nontronite, talc, saponite, hectorite, sauconite, and synthetic phyllosilicate such as laponite.

In the mica group, examples of the material able to be used in the manufacture of sheet-shaped nanoparticles may include sericite, muscovite, biotite, and phlogopite.

The phyllosilicate sheet-shaped nanoparticles of the exfoliation layer are preferably sheet-shaped particles in a single-layer or multilayer form, with an aspect ratio of 5 or more, a thickness of 0.5 nm to 300 nm, and a width of 10 nm to 100 μm.

In order to increase the application ratio of the sheet-shaped nanoparticles on the supporting substrate such as glass, the particles have to be uniformly dispersed in the suspension, and also the suspension has to be prepared so that there is no repulsion between the particles.

The concentration of the sheet-shaped nanoparticles in the suspension is appropriately 0.01 wt % to 5 wt %, preferably 0.05 wt % to 2 wt %, and more preferably 0.1 wt % to 1.0 wt %.

The suspension of the phyllosilicate sheet-shaped nanoparticles is maintained at a pH of 5.5 to 7.5 in the presence of the electrolyte, whereby the plane of the sheet-shaped nanoparticles is negatively charged and the edges thereof are uncharged.

The solution added to adjust the pH of the suspension preferably includes inorganic acid or alkali solutions such as hydrochloric acid (HCl), nitric acid (HNO₃), sulfuric acid (H₂SO₄), phosphoric acid (H₃PO₄), sodium hydroxide (NaOH), and potassium hydroxide (KOH), and acid salts such as Na₂HPO₄, NaH₂PO₄, NaHSO₄, and NaHCO₃, and alkali salts such as Ca(OH)Cl and Mg(OH)Cl.

The electrolyte added to the suspension may include an electrolyte having an alkali cation such as lithium or sodium, including sodium chloride (NaCl), lithium chloride (LiCl), potassium chloride (KCl), potassium nitrate (KNO₃), sodium nitrate (NaNO₃), sodium sulfate (Na₂SO₄), sodium sulfite (Na₂SO₃), sodium thiosulfate (Na₂S₂O₃), and pyrophosphate such as sodium pyrophosphate (Na₄P₂O₇). More preferably, any electrolyte may be used, so long as it is a 1:1 electrolyte (supporting or indifferent electrolyte) acting as a salt having high decomposition voltage with monovalent ions, such as potassium chloride (KCl), sodium chloride (NaCl), or lithium chloride (LiCl).

The concentration of the electrolyte in the suspension is 0.01 mM/L to 200 mM/L (millimoles (mM) per volume (L) of the suspension), preferably 0.05 mM/L to 100 mM/L, and more preferably 0.1 mM/L to 50 mM/L.

Furthermore, an LbL process may be adopted to apply the sheet-shaped nanoparticles on the supporting substrate such as glass. In the LbL process, the suspension may be applied through immersion, spray or spin coating.

Negatively charging the supporting substrate such as glass may be performed through oxygen or argon atmospheric-pressure plasma treatment, UV-ozone treatment, or Piranha treatment.

Positively charging the supporting substrate such as glass may be performed in a manner in which the supporting substrate is negatively charged as above and coated with the cationic polymer electrolyte (polycation) using an LBL process to realize charge inversion, thereby being positively charged.

Examples of the cationic polymer electrolyte may include PDDA (poly(diallyldimethylammonium chloride)), PEI (poly(ethylene imine)), PAA (poly(amic acid)), PSS (poly(styrene sulfonate)), PAA (poly(allyl amine)), CS (Chitosan), PNIPAM (poly(N-isopropyl acrylamide)), PVS (poly(vinyl sulfate)), PAH (poly(allylamine) hydrocloride), and PMA (poly(methacrylic acid)). The cationic polymer is not limited to the above-listed examples, and any polymer in which the independent molecule is sufficiently positively charged may be used.

The thickness of the cationic polymer electrolyte applied to realize the charge inversion falls in the range of 0.5 nm to 10 nm, and preferably 1.0 nm to 5 nm. Given the above thickness range, charge inversion of the glass supporting substrate may be induced.

### COMPARATIVE EXAMPLE

As a supporting substrate, a silicon wafer having surface characteristics similar to those of glass due to surface oxidation was used. The size of a sample had a width and a length of 50 mm each, with a thickness of 0.53 mm.

For surface charging of the silicon supporting substrate, a Piranha solution comprising concentrated sulfuric acid (H₂SO₄) and hydrogen peroxide (30%, H₂O₂) mixed at a ratio of 3:1 was used. In order to form the silanol hydroxyl group on the surface of the silicon substrate, the silicon substrate was immersed in the Piranha solution for 30 min, washed with deionized water (DI water), and dried in air.

Polyimide was formed on the silicon supporting substrate electrically charged as above. Specifically, a mixed solution comprising liquid polyamic acid as a polyimide precursor and dimethylacetamide was cast on the supporting substrate and formed to a thickness of 25 μm using a bar coater. For optimal imidization, stepwise heating was performed at 120° C. for 30 min, 180° C. for 30 min, 230° C. for 30 min, and 350° C. for 2 hr according to the polyimide manufacturer's instructions, and the heating rate of each step was 5° C./min, followed by gradual cooling from 350° C. to room temperature in a heating furnace.

In order to determine the bonding strength of the polyimide thin film bonded on the silicon supporting substrate, vertical peel strength was measured using a film adhesion tester according to ASTM D3330 (Test Method F). The supporting substrate having the polyimide thin film adhered thereto was fixed to a lower jig, and a portion of the thin film was vertically pulled upward at an angle of 90°. Here, the jig was designed to move horizontally the same distance as the pulling travel distance in order to prevent the peel strength from changing due to the movement of the peeling position during the pulling process.

The strain rate upon measurement of the peel strength, namely the load cell movement rate, was 6 inch/min, and the maximum peel strength (Newton/mm) was measured to be 24.2 N/mm, and was decreased somewhat immediately after peeling. Thereafter, a predetermined width of serration zone occurred, and the average peel strength of this zone was measured to be 22.5 N/mm.

### EXAMPLE 1

As a supporting substrate, a silicon wafer having surface characteristics similar to those of glass due to surface oxidation was used. The size of a sample had a width and a length of 50 mm each, with a thickness of 0.53 mm.

For surface charging of the silicon supporting substrate, a Piranha solution comprising concentrated sulfuric acid (H₂SO₄) and hydrogen peroxide (30%, H₂O₂), mixed at a ratio of 3:1, was used. In order to form the silanol hydroxyl group on the surface of the silicon substrate, the silicon substrate was immersed in the Piranha solution for 30 min and washed with deionized water (DI water) for 5 to 10 min. The washing process was performed through a combination of DI water spraying and immersion.

In order to positively charge the surface of the supporting substrate through charge inversion, PEI (poly(ethylene imine)) was provided as a cationic polymer electrolyte, and a 0.5 wt % PEI aqueous solution was prepared, and the silicon supporting substrate treated in the Piranha solution was immersed in the above aqueous solution. The immersion time was set to the range of 10 min to 60 min, and in the spraying process, the corresponding aqueous solution was continuously sprayed and applied on the entire surface of the supporting substrate at a predetermined pressure for 1 min to 5 min. In individual cases, if the processing time was too short, the amount of the corresponding polymer electrolyte that was applied was deficient, and thus charge inversion did not efficiently progress. On the other hand, if the processing time was too long, a coating layer having a thickness of greater than 10 nm was formed due to the excessive application, thus adversely affecting the fabrication of the flexible substrate. In this Example, the cationic PEI was applied on the silicon supporting substrate through immersion for 30 min. After the application of PEI, the supporting substrate was washed again through spraying with DI water for 5 min, thereby removing the cationic PEI that was excessively attached, resulting in a polymer layer in the form of a monolayer that was as thin as possible.

The sheet-shaped nanoparticles of the suspension were composed of montmorillonite belonging to the smectite group of the clay mineral group of phyllosilicate. Sodium montmorillonite (Na⁺-Montmorillonite, Na⁺-MMT) treated using sodium cation (Na⁺) as a guest exchange ion was used.

Various cations present between layers of natural montmorillonite may include not only Na⁺ but also Li⁺, Ca⁺, Mg⁺ and so on, and react with water molecules of dipoles upon interlayer exfoliation using water molecules. Interlayer exfoliation using water molecules is progressed in a manner in which the bonding force of water molecules and guest cations is relatively greater than the bonding force of guest cations and OH⁻ anions formed in an Si—O tetrahedral layer and an Al—O octahedral layer for each layer of interlayer montmorillonite, and thus the water molecules penetrate between the layers and swelling occurs, resulting in interlayer exfoliation. In this case, when various guest ions of montmorillonite are present, the extent of swelling of the corresponding particles due to water molecules becomes different, and thus particles that do not generate interlayer exfoliation for a predetermined period of time may be provided. Hence, the use of homogeneous montmorillonite in which the guest is a single kind of exchange cation such as sodium is regarded as important.

The prepared Na⁺-MMT powder had a particle size of 0.5 μm to 1.6 μm, and an aqueous solution having a concentration of 0.3 wt % was prepared. The Na⁺-MMT powder was added to the aqueous solution, after which sonication was performed for 2 hr to thus accelerate interlayer exfoliation, thereby manufacturing montmorillonite sheet-shaped nanoparticles (nanosheets). A small amount of precipitate that was not suspended but was precipitated in the aqueous solution was discarded, and only the supernatant was used, and the pH of the suspension was measured to be 7.8.

As described above, the silicon supporting substrate coated with PEI as the cationic polymer electrolyte and thus positively surface charged and washed with water is immersed in the montmorillonite suspension. In lieu of the immersion process, the suspension may be sprayed on the supporting substrate using a sprayer for a predetermined period of time, or the suspension may be allowed to continuously flow on the surface. In this Example, the suspension was sprayed on the silicon supporting substrate for 5 min using a spraying gun, thus inducing the application of sheet-shaped nanoparticles.

Applying the suspension was performed for the same time as in the polymer electrolyte PEI. After the coating with the suspension, washing with DI water was performed. During the washing process, DI water spraying and immersion were repeated so as not to form an unnecessary combination layer of montmorillonite sheet-shaped nanoparticles on the supporting substrate.

The supporting substrate, coated with montmorillonite and then washed, was heated to 30020 C. in air and allowed to stand for 30 min. The heating process for stabilizing the exfoliation layer serves to decompose the polymer electrolyte PEI, applied to realize the charge inversion of the supporting substrate and to emit in advance gases such as H₂, NH₃ and N₂, which may be generated during the decomposition. This is because such gases are adsorbed to the thin film layer upon formation (imidization) of the flexible substrate using polyimide and thus may adversely affect the formation of an information control display element such as a TFT on the flexible substrate. When the polymer electrolyte PDDA is used for the same purpose as in PEI, gases such as H₂, CH₄, CO, or CO₂ may be emitted. These gases may also adversely affect the formation of the information control display element on the flexible substrate, although the kinds thereof are different from the foregoing, and thus, the same effects may be obtained through heating at a similar temperature.

Most polymer electrolytes used for charge inversion may decompose upon heating in the temperature range of 150° C. to 350° C., whereas the phyllosilicate sheet-shaped nanoparticles are stable in the corresponding temperature range. In the heating process for stabilizing the exfoliation layer, the amount of applied PEI or PDDA is very small, and the emitted gases do not significantly affect processing, but the heating process is performed to preemptively prevent the above problems from occurring. Furthermore, the heating process aids in stabilizing the fixed state of montmorillonite sheet-shaped nanoparticles of the exfoliation layer, and is thus regarded as important in the present invention.

After the completion of the heating process for stabilizing the exfoliation layer, the montmorillonite sheet-shaped nanoparticles applied on the silicon supporting substrate were observed using an SEM (FIG. 1). As shown in the SEM image, delaminated particles of montmorillonite were relatively uniformly applied.

Next, a polyimide thin-film layer was formed on the silicon supporting substrate having the exfoliation layer formed thereon. A mixed solution of liquid polyamic acid as a polyimide precursor and dimethylacetamide was cast on the supporting substrate and applied to a thickness of 25 μm using a bar coater. For optimal imidization, stepwise heating was performed at 120° C. for 30 min, 180° C. for 30 min, 230° C. for 30 min, and 350° C. for 2 hr according to the polyimide manufacturer's instructions, and the heating rate of each step was 5° C./min, followed by gradual cooling from 350° C. to room temperature in a heating furnace.

In order to determine the bonding strength of the polyimide thin film bonded on the silicon supporting substrate, vertical peel strength was measured using a film adhesion tester according to ASTM D3330 (Test Method F), as in Comparative Example. Upon measurement of the peel strength, the strain rate, that is, the load cell movement rate, was 6 inch/min and the maximum peel strength (Newton/mm) was measured to be 8.6 N/mm, which was decreased to about ⅓ compared to the maximum peel strength of Comparative Example, having no exfoliation layer comprising montmorillonite. Unlike Comparative Example, the peel strength was significantly lowered compared to the maximum peel strength, and the average peel strength of the peel strength serration zone was 5.1 N/mm, which was reduced to ¼ or less compared to the case having no exfoliation layer.

### EXAMPLE 2

This Example was performed under the same conditions as in Example 1, with the exception that the suspension of phyllosilicate sheet-shaped nanoparticles was titrated to a pH of 6.5 via the addition of a small amount of hydrochloric acid (HCl), and sodium chloride at 10 mM/L, was added as the supporting electrolyte.

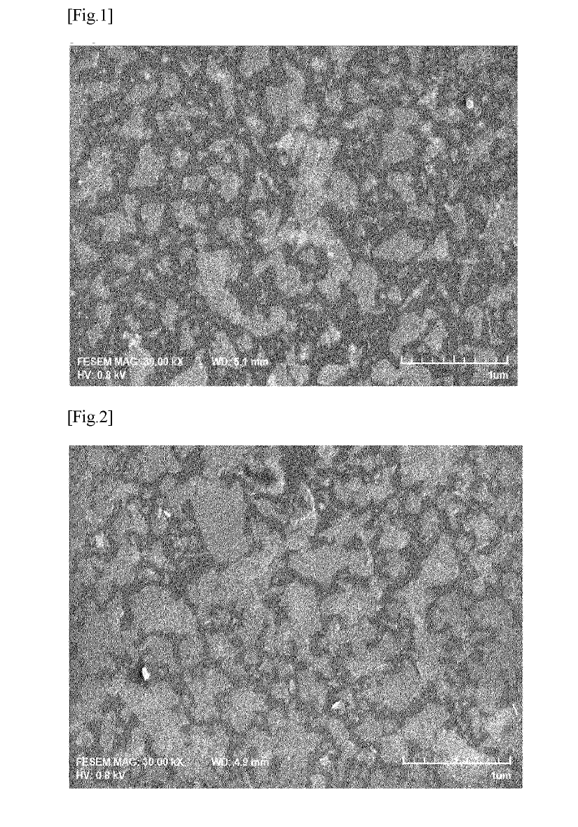

The montmorillonite sheet-shaped nanoparticles applied on the silicon supporting substrate were observed using an SEM, before the formation of a polyimide thin film after the formation of an exfoliation layer using the suspension in which the electrolyte was added and the pH was artificially titrated. The results are shown in FIG. 2. As seen in the SEM image, the density of montmorillonite sheet-shaped nanoparticles applied on the silicon substrate was increased, which means that the application ratio was remarkably increased compared to FIG. 1.

The polyimide thin film was formed on the exfoliation layer and the peel strength was measured in the same manner as in Example 1. The maximum peel strength was 5.9 N/mm, and the average peel strength was measured to be 2.4 N/mm. Thus, the application ratio was increased by virtue of a reduction in bonding force due to the sheet-shaped nanoparticles of the exfoliation layer and elimination of repulsion between the particles, consequently decreasing peel strength.

### EXAMPLE 3

This Example was performed under the same conditions as in Example 1, with the exception that the Na⁺-MMT particles used to prepare the suspension had two sizes. 15% of the particles added to the suspension were mechanically pulverized to a size of 0.3 μm or less using a ball mill, and lamellar exfoliation was conducted in the aqueous solution to give a suspension, which was then mixed with the initial particles. The concentration of Na⁺-MMT in the aqueous solution was 0.3 wt %, as in Example 1. The suspension of phyllosilicate sheet-shaped nanoparticles was titrated to a pH of 6.5 via the addition of a small amount of hydrochloric acid (HCl), and sodium chloride at 10 mM/L, was added as the supporting electrolyte.

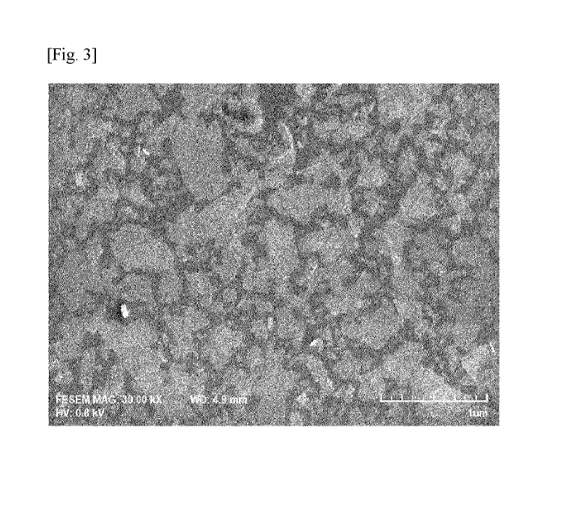

The montmorillonite sheet-shaped nanoparticles applied on the silicon supporting substrate were observed using an SEM, before the formation of a polyimide thin film after the formation of an exfoliation layer using the suspension in which the Na⁺-MMT particles having two size distributions were dispersed, the electrolyte was added and the pH was artificially titrated. The results are shown in FIG. 3. As seen in the SEM image, the density of montmorillonite sheet-shaped nanoparticles applied on the silicon substrate was increased. In particular, the exfoliation layer in a combination layer form was configured such that small particles were positioned between relatively large particles, thereby increasing the application ratio compared to the other Examples.

The polyimide thin film was formed on the exfoliation layer and the peel strength was measured in the same manner as in Example 1. The maximum peel strength was 4.6 N/mm, and the average peel strength was measured to be 1.8 N/mm. Thus, the application ratio was further increased by virtue of a reduction in the bonding force due to the sheet-shaped nanoparticles in the exfoliation layer, the control of the charge state of the particles, and the variety of particle size distributions able to fill empty spaces, thereby considerably decreasing peel strength.

### INDUSTRIAL APPLICABILITY

The present invention can be applied to an exfoliation layer for use in the fabrication of a flexible display and a method of manufacturing the same.

What is claimed is:

1. An exfoliation layer, comprising:
a cationic polymer electrolyte or organosilane, and negatively charged phyllosilicate sheet-shaped nanoparticles.

2. The exfoliation layer of claim 1, wherein the exfoliation layer comprises a lower layer composed of the cationic polymer electrolyte or organosilane and an upper layer composed of the negatively charged phyllosilicate sheet-shaped nanoparticles.

3. The exfoliation layer of claim 2, wherein the lower layer and the upper layer are repeatedly stacked.

4. The exfoliation layer of claim 3, wherein the lower layer and the upper layer are stacked in the same number of layers.

5. The exfoliation layer of claim 1, wherein a cationic polymer of the cationic polymer electrolyte is selected from the group consisting of PDDA (poly(diallyldimethylammonium chloride)), PEI (poly(ethylene imine)), PAA (poly(amic acid)), PSS (poly(styrene sulfonate)), PAA (poly(allyl amine)), CS (Chitosan), PNIPAM (poly(N-isopropyl acrylamide)), PVS (poly(vinyl sulfate)), PAH (poly(allylamine)hydrochloride), and PMA (poly(methacrylic acid)).

6. The exfoliation layer of claim 1, wherein the phyllosilicate is selected from a clay mineral group, laponite or a mica group.

7.-12. (canceled)

13. The exfoliation layer of claim 1, wherein the phyllosilicate comprises a mixture of muscovite and montmorillonite.

14. (canceled)

15. A method of manufacturing an exfoliation layer, comprising the steps of:
a) negatively charging a surface of a substrate;
b) applying a cationic polymer electrolyte or performing a silanization process; and
c) negatively charging and applying a phyllosilicate.

16. The method of claim 15, wherein the steps b) and c) are repeated after the step c).

17. The method of claim 15, wherein the step a) is performed through treatment selected from among oxygen or argon atmospheric-pressure plasma treatment, UV-ozone treatment, and Piranha treatment.

11. The method of claim 8, wherein a cationic polymer of the cationic polymer electrolyte used in the step b) is selected from the group consisting of PDDA (poly(diallyldimethylammonium chloride)), PEI (poly(ethylene imine)), PAA (poly(amic acid)), PSS (poly(styrene sulfonate)), PAA (poly(allyl amine)), CS (Chitosan), PNIPAM (poly(N-isopropyl acrylamide)), PVS (poly(vinyl sulfate)), PAH (poly(allylamine)hydrochloride), and PMA (poly(methacrylic acid)).

19. The method of claim 15, wherein the charging in the step c) comprises preparing a phyllosilicate suspension and adding an electrolyte containing an alkali cation.

20. The method of claim 19, wherein the suspension has a concentration of 0.01 to 5 wt %.

21. The method of claim 19, wherein the electrolyte is selected from the group consisting of sodium chloride (NaCl), lithium chloride (LiCl), potassium chloride (KCl), potassium nitrate (KNO₃), sodium nitrate (NaNO₃), sodium sulfate (Na₂SO₄), sodium sulfite (Na₂SO₃), sodium thiosulfate (Na₂S₂O₃), and sodium pyrophosphate (Na₄P₂O₇).

22. (canceled)

23. The method of claim 19, wherein a pH of the suspension is maintained in a range of 5.5 to 7.5 using a pH controller.

24. (canceled)

25. The method of claim 15, wherein a surface of the phyllosilicate is negatively charged, and an edge thereof is electrically neutral.

26. The method of claim 15, wherein the substrate is a supporting substrate for manufacturing a flexible display.

27. A method of manufacturing a flexible display, comprising the steps of:
a) negatively charging a surface of a substrate;
b) applying a cationic polymer electrolyte or performing a silanization process;
c) negatively charging and applying a phyllosilicate, thus obtaining an exfoliation layer;
d) forming a flexible display substrate on the exfoliation layer;
e) forming a display element on the flexible display substrate; and
f) exfoliating the flexible display substrate having the display element.

28.-39. (canceled)
